(19) United States
(12) Patent Application Publication
(10) Pub. No.: US 2009/0195847 A1
(43) Pub. Date: Aug. 6, 2009

(54) HOLOGRAPHIC RECORDING MEDIUM

(75) Inventors: Satoshi MIKOSHIBA, Yamato-shi (JP); Kazuki Matsumoto, Kawasaki-shi (JP); Rumiko Hayase, Tokyo (JP); Norikatsu Sasao, Kawasaki-shi (JP); Takahiro Kamikawa, Kawasaki-shi (JP); Masahiro Kanamaru, Fuchu-shi (JP)

Correspondence Address: Ohlandt, Greeley Ruggiero & Perle, L.L.P.;10th Floor, One Landmark Square, Stamford, CT, 06901-2682, US

(73) Assignee: KABUSHIKI KAISHA TOSHIBA

(21) Appl. No.: 12/403,548

(22) Filed: Mar. 13, 2009

Related U.S. Application Data
(63) Continuation of application No. PCT/JP2008/071171, filed on Nov. 14, 2008.

(30) Foreign Application Priority Data
Feb. 1, 2008 (JP) 2008-023255

(51) Int. Cl. G03H 1/02; G03F 7/00

(52) U.S. Cl. 359/3; 430/2

(57) ABSTRACT

A holographic recording medium is provided, which includes a recording layer containing a three-dimensional crosslinked polymer matrix, a photo-radical generating agent, and a ring-opening polymerizable compound having a radically ring-opening polymerizable alicyclic structure.

### CROSS REFERENCE TO RELATED APPLICATIONS

This is a Continuation Application of PCT Application No. PCT/JP2008/071171, filed Nov. 14, 2008, which was published under PCT Article 21(2) in English.

This application is based upon and claims the benefit of priority from prior Japanese Patent Application No. 2008-023255, filed Feb. 1, 2008, the entire contents of which are incorporated herein by reference.

### BACKGROUND OF THE INVENTION

1. Field of the Invention

The present invention relates to a holographic recording medium, a method for manufacturing the holographic recording medium, and a holographic optical information recording-reproducing apparatus.

2. Description of the Related Art

A holographic memory that records information as a hologram is now attracting much attention as a next-generation recording medium since it is capable of performing large capacity recording. A photosensitive composition for holographic recording is known in which for example, a radical polymerizable compound, a thermoplastic binder resin, a photo-radical polymerization initiator (a photo-radical generating agent) and a sensitizing dye are used as main components. This photosensitive composition for holographic recording is formed into a film to form a recording layer. Information is recorded in this recording layer through interference exposure.

In the recording layer after the interference exposure, regions strongly irradiated with light are permitted to undergo the polymerization reaction of the radical polymerizable compound. The radical polymerizable compound diffuses from the regions where the intensity of exposure light irradiated is weak to the regions where the intensity of exposure light irradiated is strong, thereby generating a gradient of concentration in the recording layer. Namely, depending on the magnitude in intensity of the interference light, differences in density of the radical polymerizable compound occur, thereby generating a difference in refractive index in the recording layer.

JP-A 11-35203 (KOKAI) has proposed a medium including a radical polymerizable compound dispersed in a three-dimensional crosslinked polymer matrix. For increasing the recording density, a radical polymerizable compound should be incorporated at high density, but cannot be incorporated at high density because of the problem of compatibility. Further, the radical polymerizable compound is shrunk by polymerization during optical recording, thus sometimes making it impossible to readout the information.

### BRIEF SUMMARY OF THE INVENTION

A holographic recording medium according to one aspect of the present invention comprises a recording layer containing a three-dimensional crosslinked polymer matrix; a photo-radical generating agent; and a ring-opening polymerizable compound having a radically ring-opening polymerizable alicyclic structure.

A method for manufacturing a holographic recording medium according to one aspect of the present invention comprises:

mixing an epoxy monomer, an alkyl silanol, a metal complex, a photo-radical generating agent, and a ring-opening polymerizable compound to obtain a raw material solution for a recording layer;

applying the raw material solution for a recording layer onto a light-transmitting substrate or interposing the raw material solution between a pair of facing light-transmitting substrates, to form a resin layer;

and heating the resin layer at a temperature in the range of from 10° C. to less than 80° C. to react the epoxy monomer, thereby forming a recording layer having a three-dimensional crosslinked polymer matrix including a structure represented by the following formula 7:

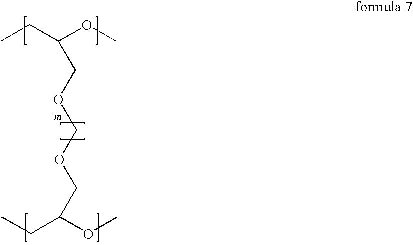

wherein m is an integer of 3 to 16.

An optical information recording/regenerating apparatus according to one aspect of the present invention comprises the aforementioned holographic recording medium; and a recording portion for recording information in the medium; and a regenerating portion for regenerating the information recorded in the medium.

### BRIEF DESCRIPTION OF THE SEVERAL VIEWS OF THE DRAWING

FIG. 1 is a schematic cross-sectional view of a transmission-type holographic recording medium in one embodiment.

FIG. 2 is a schematic diagram of a transmission-type holographic information recording-reproducing apparatus in one embodiment.

FIG. 3 is a schematic cross-sectional view of a reflection-type holographic recording medium in one embodiment.

FIG. 4 is a schematic diagram of a reflection-type holographic information recording-reproducing apparatus in one embodiment.

### DETAILED DESCRIPTION OF THE INVENTION

Next, the embodiments will be explained.

The recording layer in the holographic recording medium according to one embodiment contains a three-dimensional crosslinked polymer matrix, a photo-radical generating agent, and a ring-opening polymerizable compound having a radically ring-opening polymerizable alicyclic structure.

In this recording layer, the ring-opening polymerizable compound together with the photo-radical generating agent is present in the three-dimensional crosslinked polymer matrix. The three-dimensional crosslinked polymer matrix can be said to maintain regions in which information is recorded. When a beam of light is applied onto a predetermined region of the recording layer, the ring-opening polymerizable compound is caused to move from an unexposed region to the exposed region, thereby enabling the ring-opening polymerizable compound existing in the exposed region to polymerize due to the effect of the photo-radical generating agent. As a result, the difference in refractive index between the unexposed region and the exposed region is increased. By this mechanism, the recording of information on the recording layer is performed.

The movement of the ring-opening polymerizable compound in the three-dimensional crosslinked polymer matrix depends on a space in the three-dimensional crosslinked polymer matrix and on the size of the ring-opening polymerizable compound. The ring-opening polymerizable compound has a cyclic structure and thus inherently has a small molecular size. The ring-opening polymerizable compound, as compared with a commonly used radical polymerizable compound such as a vinyl compound or an acryl or methacryl compound, can move rapidly in the space in the three-dimensional crosslinked polymer matrix if they have the same molecular weight.

When the polymer matrix is a linear polymer, the linear polymer sways during storage for a long time, so a polymer generated by polymerization of the ring-opening polymerizable compound also moves. As a result, there arise problems such as failure to readout information. To solve such inconvenience, a three-dimensional crosslinked polymer matrix is used in the embodiments. A method that involves introducing a functional group into the terminus of a linear polymer, recording information, and then reacting the functional group to fix the matrix is also conceivable. In this case, the volume may be changed again by the reaction after recording, which adversely affects the recording, and therefore such method is preferably avoided.

The commonly used radical polymerizable compound is shrunk by polymerization, because the distance among the monomers is decreased during polymerization. Examples of such radical polymerizable compound include a vinyl compound and an acryl or methacryl compound. Particularly, styrene, typified by the vinyl compound, is shrunk by about 15% due to polymerization of styrene molecules. This shrinkage causes a shift in the position of recorded information. In addition, volumetric shrinkage distorts the information. The ring-opening polymerizable compound in the embodiments can, by the ring-opening reaction, decrease the reduction in the distance among molecules caused by polymerization.

For example, styrene oxide (STO), which is a cationic polymerization monomer having a molecular weight similar to that of styrene (ST), shows a shrinkage of about 9%, which is lower than the shrinkage of the vinyl compound. In the case of 1-phenyl-1-cyclopropyl ethene (PCP), a further lower shrinkage can be expected. The ring-opening reaction of styrene oxide is a 3-membered ring reaction called a 1,3-reaction, while the ring-opening reaction of PCP is a 1,5-reaction in which both a vinyl group and cyclopropyl group are reacted. As a result, the structure obtained by polymerization of PCP has a wider space, leading to a reduction in the shrinkage.

These compounds are as follows:

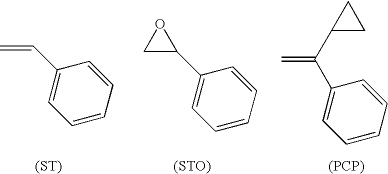

By the mechanism shown above, the recording of information is performed. The recording density depends on the content of the ring-opening polymerizable compound in the recording layer. Accordingly, the amount of the ring-opening polymerizable compound contained in the recording layer is preferably larger, as long the optical recording formed by polymerization is not destroyed.

To record information, the difference Δn in refractive index between the exposed region and the unexposed region is desirably larger. The refractive index may be relatively decreased by exposure to light, but generally a method of relatively increasing the refractive index by exposure to light is used. In this case, the refractive index of the ring-opening polymerizable compound used is larger than that of the polymer matrix.

In the embodiments, the ring-opening polymerizable compound includes, but is not limited to, a vinyl cyclopropane compound, a cyclic sulfide compound, a bicylobutane compound, a vinyl cyclic butane compound, a vinyl cyclic sulfone compound, a cyclic ketene acetal compound, a methylene dioxolane compound, a cyclic allyl sulfide compound, a benzocyclobutane compound, a xylylene dimer compound, and a cyclic disulfide compound.

Examples of a cyclic cyclopropane compound, a cyclic sulfide structure, a vinyl cyclic sulfone, a bicyclobutane structure and a 4-methylene-1,3-dioxane structure are shown in the following general formulae:

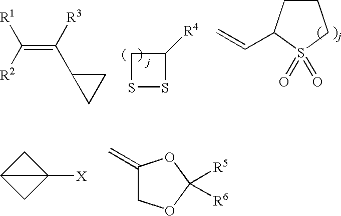

Examples of a cyclic ketene acetal structure, 8-methylene-1,4-dioxaspiro-[4,5]-deca-6,9-diene structure, a cyclic allylsulfide structure, and a cyclic α-oxyacrylate structure are shown in the following general formulae:

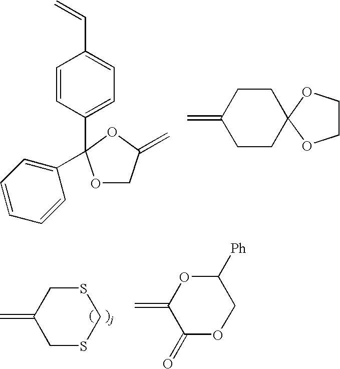

Examples of a benzocyclobutene structure, an o-xylylene dimer structure, a structure having in its molecule an exomethylene structure and a spiro-orthocarbonate structure, and a structure having in its structure an exomethylene structure and a spiro-orthoester structure are shown in the following general formulae:

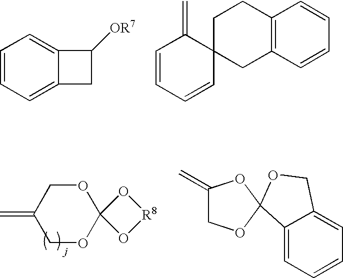

wherein R¹, R², R³ and R⁴ each represent a hydrogen atom or a substituted or unsubstituted organic group; X represents CO₂H or CN; R⁵ and R⁶ each represent a hydrogen atom or a substituted or unsubstituted organic group; R⁷ represents a hydrogen atom or a substituted or unsubstituted organic group; R⁸ represents a substituted or unsubstituted organic group; and j is an integer of 1 to 5.

Among the compounds shown above, 1-cyclopropyl-1-phenyl ethene, 1-cyclopropyl-1-tribromophenyl ethene, and 1-cyclopropyl-1-naphthyl ethene are effective. This is because the reaction rate of the radical reaction is high, and information can be rapidly recorded.

Generally, the refractive index of an aromatic ring-containing group is relatively high, while the refractive index of an aliphatic hydrocarbon group is relatively low. Accordingly, when an aromatic ring-containing group is contained, the refractive index of the ring-opening polymerizable compound can be made higher than the average refractive index of the recording layer, and when many aliphatic hydrocarbon moieties are present, the average refractive index of the recording layer can be made further lower. The aromatic ring-containing group includes, for example, a phenyl group, a phenylene group, a naphthyl group, a naphthylene group and a carbazole group. The benzene ring in the aromatic ring-containing group may be substituted with a halogen such as chloride, bromine or iodine, a sulfur compound such as thiol, a methylthio group, an ethylthio group or a phenylthio group, an alkyl group, or an aromatic group.

When the ring-opening polymerizable compound is free of an aromatic ring, a hologram in which a recorded region has a low refractive index can be recorded. In this case, the average refractive index of the recording layer should be higher than that of the ring-opening polymerizable compound. Accordingly, it is not always necessary for an aromatic ring to be contained in the ring-opening polymerizable compound.

In the embodiments, a usual radical polymerizable compound may be contained as a radically polymerizable compound in addition to the ring-opening polymerizable compound. In this case, the amount of the usual radical polymerizable compound is limited to 3/2 or less based on the weight of the ring-opening polymerizable compound.

The usual radical polymerizable compound has already been used in various fields and is a substance advantageous to mass production and cost. The performance of the holographic recording medium can further be improved by incorporation of the usual radical polymerizable compound in such a range that the effect of the ring-opening polymerizable compound is not deteriorated. The usual radical polymerizable compound can be used, for example, as a copolymer with the ring-opening polymerizable compound.

Volumetric shrinkage accompanying polymerization of the usual radical polymerizable compound is known to generally reduce signal bER (bit error rate) and SNR (signal-to-noise ratio). The copolymer as described above can decrease reduction in bER and SNR, so the usual radical polymerizable monomer can also be used. When the content of the ring-opening polymerizable compound in the copolymer is 40% or more, the volumetric shrinkage can be suppressed to the allowable range, and thus information recorded with improved bER and SNR can be reproduced.

The polymerizable group in the usual radical polymerizable compound can be selected, for example, from the group consisting of an acryl group, a methacryl group, a vinyl group, an epoxy group, and an oxetane group.

When an inexpensive medium is to be provided, an inexpensive hydrocarbon-based polymer of low refractive index is advantageously used in the polymer matrix. Accordingly, the radical polymerizable compound desirably contains an aromatic ring-containing group. A radical polymerizable compound having an aromatic ring-containing group and a polymerizable group includes, for example, vinyl naphthalene, vinyl carbazole, tribromophenyl acrylate, styrene, and divinyl phenylene.

The ring-opening polymerizable compound is incorporated preferably in an amount of 1 to 40% by weight based on the entire recording layer. When the amount is lower than 1% by weight, the recording density may be extremely reduced. Further, due to the too high proportion of the polymer matrix, the movement of the ring-opening polymerizable compound may be inhibited, which reduces recording sensitivity. On the other hand, when the amount is higher than 40% by weight, the content of the polymer matrix is relatively low, thus permitting easy deformation of the optical recording formed. In this case, it may be difficult to readout the recorded information. The content of the ring-opening polymerizable compound is more preferably 5 to 15% by weight based on the entire recording layer.

It is necessary that the polymer matrix be composed of a three-dimensional crosslinked polymer. The three-dimensional crosslinked polymer can be formed by an arbitrary reaction, and the reaction is not particularly limited. Examples of the reaction that can be used herein include a reaction between an isocyanate and a hydroxyl group, a reaction between α,β-unsaturated carbonyl and thiol, and a ring-opening cationic reaction of epoxy or oxetane. Preferable among these reactions is the ring-opening cationic reaction such as epoxy-amine polymerization, epoxy-acid anhydride polymerization, epoxy homopolymerization, or oxetane homopolymerization. The ring-opening cationic reaction is more preferably ring-opening cationic polymerization, most preferably homopolymerization of epoxy in the presence of an aluminum complex and silanol as catalysts.

The amine used in epoxy-amine polymerization is an arbitrary compound that gives a cured product by reaction with a diglycidyl ether selected from the group consisting of 1,6-hexanediol diglycidyl ether and diethyleneglycol diglycidyl ether.

Specifically, the amine includes, for example, ethylenediamine, diethylenetriamine, triethylenetetraamine, tetraethylenepentaamine, pentaethylenehexaamine, hexamethylenediamine, menthenediamine, isophoronediamine, bis(4-amino-3-methyldichlohexyl)methane, bis(aminomethyl)cyclohexane, N-aminoethylpiperazine, m-xylylenediamine, 1,3-diaminopropane, 1,4-diaminobutane, trimethylhexamethylenediamine, iminobispropylamine, bis(hexamethylene)triamine, 1,3,6-trisaminomethylhexane, dimethylaminopropylamine, aminoethylethanolamine, tri(methylamino)hexane, m-phenylenediamine, p-phenylenediamine, diaminodiphenylmethane, diaminodiphenylsulfone, and 3,3′-diethyl-4,4′-diaminodiphenylmethane.

An aliphatic primary amine is preferably used because it is curable at room temperature at a high curing rate. Preferable among these amines are diethylenetriamine, triethylenetetraamine, tetraethylenepentaamine, pentaethylenehexaamine, and iminobispropylamine. It is desirable to use such amine in a mixing amount in which the amount of NH— of the amine is 0.6- to 2-fold or less relative to the equivalent of oxirane of 1,6-hexanediol diglycidyl ether or diethylene glycol diglycidyl ether. Where the amine is mixed in an amount smaller than 0.6-fold or larger than 2-fold relative to the equivalent, the resolution may be lowered.

As the epoxy monomer, it is possible to employ, for example, glycidyl ether. Specific examples include ethyleneglycol diglycidyl ether, 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, and 1,12-dodecanediol diglycidyl ether.

The epoxy homopolymer can be synthesized by cationic polymerization of an epoxy monomer. The epoxy monomer includes, for example, glycidyl ether. Specific examples include ethyleneglycol diglycidyl ether, 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, and 1,12-dodecanediol diglycidyl ether.

When the easiness of moving of the ring-opening polymerizable compound in the polymer matrix is taken into consideration, the epoxy monomer is preferably a compound represented by the following general formula (1):

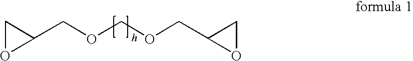

(wherein h is an integer ranging from 8 to 12.)

Specific examples of such compounds include 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, and 1,12-dodecanediol diglycidyl ether.

In cationic polymerization of the epoxy monomer, a metal complex and alkyl silanol are used as catalysts.

The metal complex includes the compounds represented by the following general formulae (2), (3) and (4):

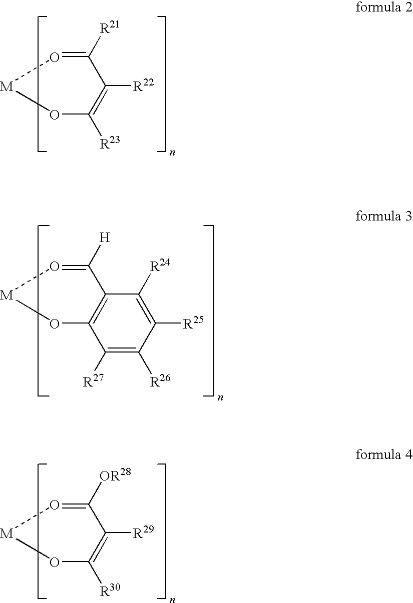

(wherein M is selected from the group consisting of Al, Ti, Cr, Mn, Fe, Co, Ni, Cu, Zr, Zn, Ba, Ca, Ce, Pb, Mg, Sn and V; R²¹, R²² and R²³ may be the same or different and are independently selected from the group consisting of a hydrogen atom and a substituted or unsubstituted alkyl group having 1 to 10 carbon atoms; R²⁴, R²⁵, R²⁶ and R²⁷ may be the same or different and are independently selected from the group consisting of a hydrogen atom and a substituted or unsubstituted alkyl group having 1 to 10 carbon atoms; R²⁸, R²⁹ and R³⁰ may be the same or different and are independently selected from the group consisting of a hydrogen atom and a substituted or unsubstituted alkyl group having 1 to 10 carbon atoms; and n is an integer of 2 to 4.)

When the compatibility of the metal complex with the three-dimensional crosslinked polymer matrix and the catalytic capacity thereof are taken into consideration, M is preferably aluminum (Al) or zirconium (Zr), and each of R²¹ to R³⁰ is preferably acetyl acetone or an alkylacetyl acetate such as methylacetyl acetate, ethylacetyl acetate, or propylacetyl acetate. The metal complex is most preferably aluminum tris(ethylacetyl acetate).

The alkyl silanol includes the compounds represented by the following general formula (5):

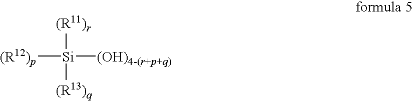

(wherein R¹¹, R¹² and R¹³ may be the same or different and are independently selected from the group consisting of a substituted or unsubstituted alkyl group having 1 to 30 carbon atoms, a substituted or unsubstituted aromatic group having 6 to 30 carbon atoms, and a substituted or unsubstituted aromatic heterocyclic group having 3 to 30 carbon atoms, and r, p and q are individually an integer of 0 to 3 with a proviso that r+p+q is 3 or less.)

In the general formula (5), the alkyl group that can be introduced as R¹¹, R¹² or R¹³ includes, for example, a methyl group, an ethyl group, a propyl group, a butyl group, a pentyl group and a hexyl group. The aromatic group that can be introduced as R¹¹, R¹² or R¹³ includes, for example, a phenyl group, a naphthyl group, a tolyl group, a xylyl group, a cumenyl group and a mesityl group. The aromatic heterocyclic group includes, for example, a pyridyl group and a quinolyl group. At least one of hydrogen atoms in the alkyl group, aromatic group and aromatic heterocyclic group may be substituted by a substituent group such as a halogen atom.

Specific examples of the alkyl silanol include diphenyl disilanol, triphenyl silanol, trimethyl silanol, triethyl silanol, diphenyl silanediol, dimethyl silanediol, diethyl silanediol, phenyl silanetriol, methyl silanetriol, and ethyl silanetriol. In consideration of the compatibility thereof with the three-dimensional crosslinked polymer matrix and the catalytic capacity thereof, the alkyl silanol is preferably diphenyl disilanol or triphenyl silanol.

A compound having an effect similar to that of the alkyl silanol represented by the general formula (5) includes the phenolic compounds represented by the following general formula (6):

R¹⁴—Ar—OH (6)

(wherein R¹⁴ is a substituted or unsubstituted alkyl group having 1 to 30 carbon atoms or a substituted aromatic group having 6 to 30 carbon atoms; and Ar is a substituted or unsubstituted aromatic group having 3 to 30 carbon atoms.)

The alkyl group that can be introduced as R¹⁴ includes, for example, a methyl group, an ethyl group, a propyl group, a butyl group, a pentyl group, a hexyl group, a trifluoromethyl group, and a pentafluoroethyl group. At least one of hydrogen atoms in the alkyl group may be substituted by a substituent group such as a halogen atom.

The substituted aromatic group that can be introduced as R¹⁴ includes, for example, HO(C₆H₆)SO₂—, HO(C₆H₆)C(CH₃)₂—, and HO(C₆H₆)CH₂—.

The aromatic group that can be introduced as Ar includes, for example, a phenyl group, a naphthyl group, a tolyl group, a xylyl group, a cumenyl group, and a mesityl group. At least one of hydrogen atoms in the aromatic group may be substituted by the aforementioned substituent group.

Since the phenolic compound represented by the aforementioned general formula (6) is capable of substitution reaction with the ligand of the metal complex, the phenolic compound has an effect similar to that of the alkyl silanol represented by the aforementioned general formula (5).

Specific examples of the phenolic compound represented by the general formula (6) include HO(C₆H₆)SO₂(C₆H₆)OH, HO(C₆H₆)CH₂(C₆H₆)OH, HO(C₆H₆)C(CH₃)₂(C₆H₆)OH, CF₃(C₆H₆)OH, and CF₃CF₂(C₆H₆)OH. In consideration of the compatibility thereof with the three-dimensional crosslinked polymer matrix and the catalytic capacity thereof, the phenolic compound is preferably CF₃(C₆H₆)OH or HO(C₆H₆) SO₂ (C₆H₆)OH.

A cationic polymerization catalyst which is composed of a combination of the alkyl silanol represented by the aforementioned general formula (5) with the metal complex represented by any of the aforementioned general formulae (2), (3) and (4) is capable of promoting the polymerization reaction of the ring-opening polymerizable compound at room temperature (in the vicinity of 25° C.). Therefore, it is possible to form the three-dimensional crosslinked polymer matrix without necessitating the application of heat history to the ring-opening polymerizable compound and to the photo-radical generating agent. The three-dimensional crosslinked polymer matrix formed can be represented by the following general formula (7):

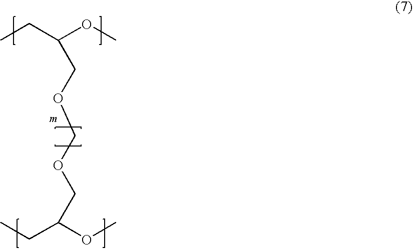

(wherein m is an integer of 3 to 16.)

Even when the alkyl silanol is replaced by the phenolic compound represented by the aforementioned general formula (6), almost the same effects as described above can be obtained.

Moreover, the catalytic components such as the alkyl silanol represented by the aforementioned general formula (5), the phenolic compound represented by the aforementioned general formula (6), and the metal complex represented by any of the aforementioned general formulae (2), (3) and (4) can exist in the polymer matrix without reacting with the three-dimensional crosslinked polymer matrix obtained through the polymerization. Further, ionic impurities are not generated.

When the recording layer containing the three-dimensional crosslinked polymer matrix, the ring-opening polymerizable compound and the photo-radical generating agent is exposed to light by irradiating a predetermined region thereof with light, the ring-opening polymerizable compound moves to the exposed region. A space generated by the movement of the ring-opening polymerizable compound is then occupied by the catalytic components existing in the matrix. As a result, the change in refractive index becomes more prominent.

Even if a reaction occurs between the catalytic components, there does not arise any problem. From the viewpoint of the ease with which the shrinkage and strain of the medium can be controlled to attain a lower reaction rate and to prevent a violent reaction, it is more preferable to employ the phenolic compound represented by the general formula (6) rather than the alkyl silanol represented by the general formula (5).

Further, these catalytic components do not generate decomposition products such as alcohol or impurities. When the catalytic action is to be generated, it is not necessary for water to exist in the medium and therefore it is possible to employ the medium in a stable dried state.

The catalyst components such as the metal complex and alkyl silanol as described above function in increasing the adhesion between a substrate for maintaining the medium and the recording layer. When a molecule which is highly polarized therein, such as the metal complex, coexists with a hydroxyl group of silanol in the recording layer, the adhesion of the recording layer to various substrates such as those made of glass, polycarbonate, acrylic resin, polyethylene terephthalate (PET), etc., can be enhanced.

When the adhesion of the recording layer to the substrate is enhanced, it is possible to prevent the peel-off of the recording layer even if volumetric shrinkage or volumetric expansion are generated at a minute exposed or unexposed region during writing of information by interference wave. Since the information thus recorded can be maintained without generating any distortion, the recording performance can be further improved. Further, the metal complex and alkyl silanol exist in the matrix without deactivation.

For this reason, the information thus written can be fixed through post-baking of the medium, thus prevent it from changing with time. When the recording medium is subjected to exposure by interference wave, the ring-opening polymerizable compound is polymerized to increase the density of the exposed region, thus increasing the refractive index. On the other hand, at the unexposed region, the density thereof is reduced due to the movement of the ring-opening polymerizable compound therefrom, thus decreasing the refractive index. The ring-opening polymerizable compound in this case moves more easily as the matrix of the medium is made lower in density. Namely, as the crosslink density of the three-dimensional crosslinked polymer matrix becomes lower, the ring-opening polymerizable compound moves more easily to give a medium of higher sensitivity.

However, in the three-dimensional crosslinked polymer matrix of low crosslink density, the ring-opening polymerizable compound or its polymer moves to an unexposed region of spatially low density. Therefore, the crosslink density of the polymer matrix is desirably decreased so as to enable the ring-opening polymerizable compound to more easily move when information is recorded through exposure of the recording layer to an interference wave. After the information is written in the recording layer, the crosslink density of the matrix can be effectively increased by post-baking in order to fix the information. Since the recording medium in the embodiments can increase the crosslink density of the matrix by post-baking, the recording performance can be improved.

The post-baking is performed desirably at a temperature in the range of 40 to 100° C. If the temperature is lower than 40° C., the crosslink density of the matrix is hardly increased. On the other hand, if the temperature is higher than 100° C., the molecular motion of the matrix becomes active, thus changing the recorded information and making the readout of the information impossible in some cases.

As described above, the density of the recording layer is increased in the exposed region, while the density of the unexposed region is decreased, when information is recorded by an interference wave. Due to a difference in density of the recording layer, the catalyst components such as the metal complex and alkyl silanol move from the exposed region to the unexposed region. This movement of these catalyst components promotes the movement of the ring-opening polymerizable compound to the exposed region. The catalyst components that have moved to the unexposed region have an action of decreasing the refractive index of the unexposed region.

The three-dimensional crosslinked polymer matrix (cured product of epoxy resin) that has been polymerized using the metal complex and alkyl silanol as catalysts is transparent to light ranging from visible light to ultraviolet rays and has optimal hardness. Namely, since the polymer matrix is transparent to the exposure wavelength, the absorption of light by the photo-radical generating agent cannot be obstructed, thereby making it possible to obtain a three-dimensional crosslinked polymer matrix having such hardness as to allow the ring-opening polymerizable compound to diffuse appropriately therein. As a result, it is now possible to manufacture a holographic recording medium excellent in sensitivity and diffraction efficiency. Furthermore, since the three-dimensional crosslinked polymer matrix has suitable hardness, it is possible to inhibit the recording layer from being shrunk in the region where the ring-opening polymerizable compound has been polymerized.

Use of the aforementioned epoxy monomer in formation of the three-dimensional crosslinked polymer matrix is advantageous in the following respects. Namely, when the epoxy monomer is used, the movement, generated upon exposure, of the ring-opening polymerizable compound will not be inhibited. This is because a sufficient space can be obtained for movement of the three-dimensional crosslinked polymer matrix; the crosslink density is not partially increased; and the polarity of the matrix is so low that the movement of the ring-opening polymerizable compound is not obstructed. Therefore, it is now possible to excellently perform hologram writing.

The recording layer in the holographic recording medium in the embodiments contains a photo-radical generating agent in addition to the ring-opening polymerizable compound and the polymer matrix.

The photo-radical generating agent includes, for example, an imidazole derivative, an organic azide compound, titanocenes, organic peroxides, and thioxanthone derivatives. To be more specific, the photo-radical generating agent includes, for example, benzyl, benzoin, benzoin-ethyl ether, benzoin isopropyl ether, benzoin butyl ether, benzoin isobutyl ether, 1-hydroxy cyclohexyl phenyl ketone, benzyl methyl ketal, benzyl ethyl ketal, benzyl methoxy ethyl ether, 2,2′-diethyl acetophenone, 2,2′-dipropyl acetophenone, 2-hydroxy-2-methyl propiophenone, p-tert-butyl trichloro acetophenone, thioxanthone, 2-chloro thioxanthone, 3,3′4,4′-tetra(t-butyl peroxy carbonyl)benzophenone, 2,4,6-tris(trichloromethyl)-1,3,5-triazine, 2-(p-methoxy phenyl)-4,6-bis(trichloromethyl)-1,3,5-triazine, 2-[(p-methoxy phenyl)ethylene]-4,6-bis(trichloromethyl)-1,3,5-triazine, Irgacure Nos. 149, 184, 369, 651, 784, 819, 907, 1700, 1800 and 1850 manufactured by Ciba Specialty Chemicals, di-t-butyl peroxide, dicumyl peroxide, t-butyl cumyl peroxide, t-butyl peroxide acetate, t-butyl peroxy phthalate, t-butyl peroxy benzoate, acetyl peroxide, isobutyl peroxide, decanoyl peroxide, lauroyl peroxide, benzoyl peroxide, t-butyl hydroperoxide, cumene hydroperoxide, methyl ethyl ketone peroxide, and cyclohexanone peroxide.

The photo-radical generating agent is incorporated preferably in an amount of 0.1 to 10% by weight based on the ring-opening polymerizable compound. If the content of the photo-radical generating agent is less than 0.1% by weight, a sufficient change in refractive index may not be obtained. On the other hand, if the content of the photo-radical generating agent exceeds 10% by weight, the light absorption by the recording layer becomes so large that the resolution may be deteriorated. The content of the photo-radical generating agent is more preferably 0.5 to 6% by weight based on the ring-opening polymerizable compound.

If necessary, a sensitizing dye such as cyanine, merocyanine, xanthene, coumarin or eosin, a silane coupling agent, and a plasticizer may be incorporated.

The predetermined components described above are mixed together to prepare a raw material solution for the recording layer. The resulting raw material solution for the recording layer is used to form a resin layer on a predetermined substrate, followed by forming a polymer matrix, to form a recording layer.

For example, the raw material solution is applied onto a light-transmitting substrate to form a resin layer. As the light-transmitting substrate, a glass substrate or a plastic substrate for example can be used. The raw material solution can be applied by using casting or spin coating. Alternatively, the raw material solution may be poured into a space formed between a pair of glass substrates superimposed via a resin spacer, thereby forming a resin layer.

The resin layer thus formed is then heated using an oven, a hot plate, etc., to advance the radical polymerization of the epoxy monomer, thus forming a three-dimensional crosslinked polymer matrix. The temperature in this heating step is not particularly limited, but is desirably 10° C. or more and less than 80° C., more desirably 10° C. or more and less than 60° C. If the heating temperature is lower than 10° C., it may become difficult to form the three-dimensional cross-linking. On the other hand, if the heating temperature is 80° C. or more, the reaction may vigorously occur, thereby narrowing voids of the three-dimensional crosslinked matrix, which may result in a reduction in the moving velocity of the ring-opening polymerizable compound in the polymer matrix. Further, if the heating temperature is 80° C. or more, the reaction of the ring-opening polymerizable compound may take place. Since this reaction easily takes place at room temperature, a method of curing the resin layer at room temperature is preferable.

The thickness of the recording layer is preferably in the range of 0.1 to 5 mm. If the thickness is less than 0.1 mm, the angular resolution may deteriorate, thereby making it difficult to perform multiple recording. On the other hand, if the thickness exceeds 5 mm, the transmissivity of the recording layer may be lowered, thus deteriorating the performance of the recording layer. The thickness of the recording layer is more preferably in the range of 0.2 to 2 mm.

When the holographic recording medium in the embodiments is used in recording, the recording medium is irradiated with information light and reference light. By allowing these two lights to interfere with each other in the interior of the recording layer, the recording or regeneration of the hologram is performed. The type of hologram (holography) to be recorded may be either a transmission type hologram (transmission type holography) or a reflection type hologram (reflection type holography). The method of generating the interference between the information light and the reference light may be a two-beam interference method or a coaxial interference method.

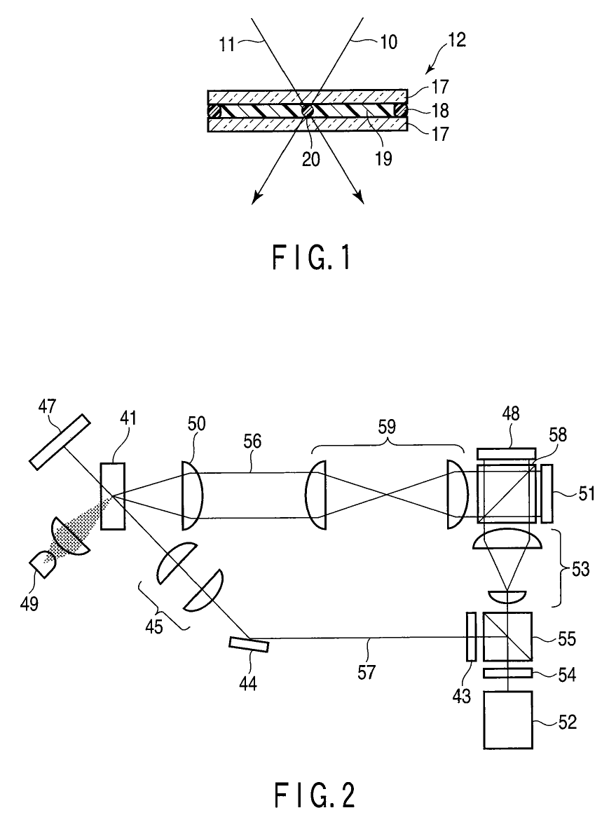

FIG. 1 shows a diagram schematically illustrating the holographic recording medium to be employed in a two beam interference holography recording medium and also illustrating the information light and the reference light in the vicinity of the holographic recording medium. As shown in FIG. 1, the holographic recording medium 12 is composed of a pair of transparent substrates 17, between which a spacer 18 and a recording layer 19 are sandwiched. The transparent substrates 17 are made respectively of glass or a plastic such as polycarbonate. The recording layer 19 contains the specific three-dimensional crosslinked polymer matrix, the ring-opening polymerizable compound and the photo-radical generating agent as described above.

As the holographic recording medium 12 is irradiated with information light 10 and reference light 11, these beams are intersected in the recording layer 19 as shown in the figure. As a result, interference between these beams occurs, thereby forming a transmission type hologram in a modulated region 20.

FIG. 2 is a diagram schematically illustrating one example of the holographic recording/regenerating apparatus. The holographic recording/regenerating apparatus shown in FIG. 2 is a hologram type optical recording/regenerating apparatus where a transmission type two-beam interference method is utilized.

The light irradiated from a light source device 52 is introduced, via an optical element 54 for optical rotation, into a polarization beam splitter 55. As the light source device 52, it is possible to employ a GaN-type semiconductor laser having an external resonator. Such light source device emits light having a wavelength of 405 nm as coherent light.

In this case, a half-wavelength plate for wavelength of 405 nm can be used as the optical element 54 for optical rotation. The direction of the half-wavelength plate is regulated such that the contrast of a hologram recorded on the transmission type recording medium 41 is maximized.

The light introduced into the polarization beam splitter 55 is divided into two lights, one of which is introduced via a beam expander 53 into a polarization beam splitter 58 and given information from a reflection type spatial beam modulator 51. Further, the light passing through a relay lens 59 is applied as information light 56 via an objective lens 50 onto a transmission type holographic optical recording medium 41. A liquid crystal panel can be used as the reflection type spatial beam modulator 51.

A reference number 48 is a two-dimensional light detector, and for example, a CCD array can be used.

The other light divided by the polarization beam splitter 55 passes through an optical element 43 for optical rotation, to form a reference light 57. A half-wavelength plate for a wavelength of 405 nm can be used as the optical element 43 for optical rotation. The direction of the half-wavelength plate is adjusted so as to make the information light 56 and the reference light 57 equal to each other in the transmission type holographic recording medium 41. The reference light 57 passes through a mirror 44 and relay lenses 45 and is made incident on the transmission type holographic optical recording medium 41.

To stabilize the recorded hologram, the unreacted ring-opening polymerizable compound may, after recording, be polymerized by irradiation with light from an ultraviolet light source device 49. The light emitted from the ultraviolet light source device 49 may be an arbitrary light and is not particularly limited as long as it is capable of polymerizing the unreacted ring-opening polymerizable compound. From the viewpoint of high emission efficiency of ultraviolet light, the ultraviolet light source device includes, for example, a xenon lamp, a mercury lamp, a high-pressure mercury lamp, a mercury xenon lamp, a gallium nitride series light-emitting diode, a gallium nitride series semiconductor laser, an excimer laser, a tertiary higher harmonic wave component (355 nm) of an Nd:YAG laser, or a quaternary higher harmonic wave component (266 nm) of an Nd:YAG laser.

When the apparatus shown in the figure is used in recording on the medium, the transmission type holographic optical recording medium is mounted on the optical recording reproducing apparatus. Recording can be performed by using an angular multiplexing recording method in which the angle of incidence of the reference light 57 is changed for each page by driving the mirror 44. For example, the holographic angle multiplexing recording of 40 pages per spot is performed with a recording spot with a radius of 3 mm and with the reference light at an angular interval of 0.5°, and the regenerated images are used to evaluate recording characteristics.

The light intensity on the surface of the optical recording medium 41 is for example 0.5 mW, and the exposure time per page can be 1 second. The following information light region only was indicated in the reflection type spatial beam modulator 51. Information was handled in this information light region using a region of 144×144 (20736) pixels constituting 1296 panels in total, each panel consisting of 4×4 (16) pixels. As the method of indicating information, a 16:3 modulation method wherein 3 of 16 (4×4) pixels are used as bright pixels can be used to indicate information in 565 ways (1 byte) in 1 panel, and the amount of information per page is 1296 bytes.

The recorded hologram can be reproduced with a CCD array 48. In reproduction, the optical element 54 for optical rotation is rotated to irradiate the optical recording medium 41 with the reference light 57 only. The mirror 47 is regulated so as to reflect the reference light 57 perpendicularly, and the direction of the optical element 43 for optical rotation is regulated such that the intensity of reproduced light obtained in CCD array 48 is maximized. During reproduction, the light intensity in the optical recording medium can be, for example, 0.5 mW.

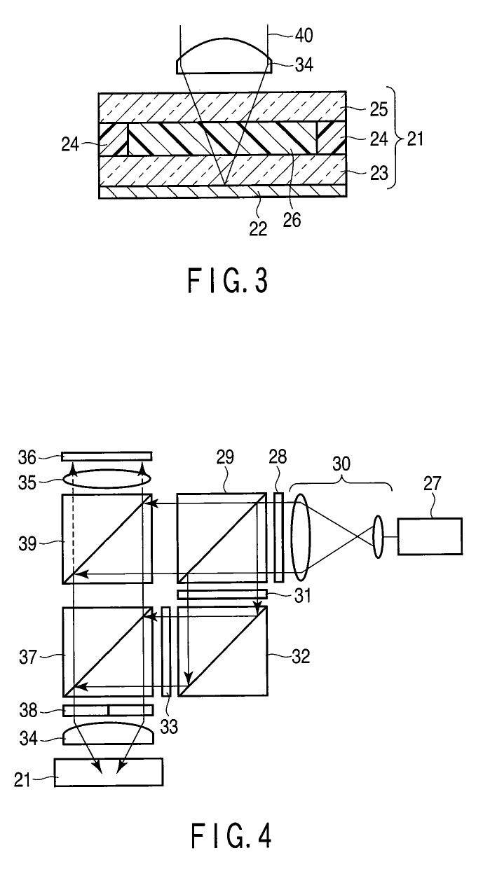

The recording medium according to the embodiments can also be used as a reflection type holographic recording medium. In this case, the recording of information can be performed as shown in FIG. 3, for example. FIG. 3 is a schematic view illustrating the reflection type holographic recording medium, as well as the information light and the reference light in the vicinity of the holographic recording medium. As shown in FIG. 3, the holographic recording medium 21 includes a pair of transparent substrates 23 and 25, each made of glass or a plastic such as polycarbonate, a spacer 24 and a recording layer 26 which are sandwiched between these transparent substrates 23 and 25, and a reflection layer 22 fixed to the substrate 23. The recording layer 26 contains the specific three-dimensional crosslinked polymer matrix, the ring-opening polymerizable compound and the photo-radical generating agent as described above.

In the reflection type holographic recording medium 21 similar to the transmission type hologram, the reflection type holographic recording medium 21 is irradiated with an information light and a reference light 40, and these lights are intersected to each other in the recording layer 26, thereby generating an interference between these lights and forming a reflection type hologram in the modulated region (not shown).

Next, the method of recording information in the reflection type holographic recording medium 21 will be explained with reference to FIG. 4.

As in the case of the transmission type holographic recording/regenerating apparatus, the light source device 27 of the holographic recording/regenerating apparatus shown in FIG. 4 preferably makes use of a laser which emits a linearly polarized coherent light. As the laser, it is possible to employ a semiconductor laser, an He—Ne laser, an argon laser and a YAG laser.

The light beam emitted from the light source device 27 is expanded in beam diameter by the beam expander 30 and then transmitted as a parallel beam to the optical element 28 for optical rotation.

The optical element 28 for optical rotation is constructed such that it can emit, through the rotation of the plane of polarization of the previous beam of light, a light including a polarized light component where the plane of polarization is parallel with the plane of the drawing (hereinafter referred to as a P-polarized light component) and a polarized light component where the plane of polarization is perpendicular to the plane of the drawing (hereinafter referred to as a S-polarized light component). Alternatively, it is possible to enable the optical element 28 to emit, by making the previous beam of light into a circular polarization or an elliptic polarization, a light including a polarized light component where the plane of polarization is parallel with the plane of the drawing. As the optical element 28 for optical rotation, it is possible to employ, for example, a half- or quarter-wavelength plate.

Of these lights that have been emitted from the optical element 28 for optical rotation, the S-polarized light component is reflected by the polarized beam splitter 29 and hence transmitted to a transmission type special beam modulator 31. Meanwhile, the P-polarized light component passes through the polarized beam splitter 29. This P-polarized light component is utilized as a reference light.

The transmission type special beam modulator 31 is provided with a large number of pixels, which are arrayed matrix-like as in the case of a transmission type liquid crystal display device, so that the light emitted from this special beam modulator 31 can be switched from the P-polarized light component to the S-polarized light component and vice versa for each pixel. In this manner, the transmission type special beam modulator 31 emits the information light provided with a two-dimensional distribution regarding the plane of polarization in conformity with the information to be recorded.

The information light emitted from this special beam modulator 31 then enters another polarized beam splitter 32. This polarized beam splitter 32 acts to reflect only the S-polarized light component of the previous information light while permitting the P-polarized light component to pass therethrough.

The S-polarized light component that has been reflected by the polarized beam splitter 32 passes, as an information light provided with a two-dimensional intensity distribution, through the electromagnetic shutter 33 and enters another polarized beam splitter 37. This information light is then reflected by the polarized beam splitter 37 and enters a halving optical element 38 for optical rotation.

This halving optical element 38 for optical rotation is constructed such that it is partitioned into a right side portion and a left side portion, which differ in optical properties from each other. Specifically, among the information lights, for example, the light component entering into the right side portion of this halving optical element 38 for optical rotation is emitted therefrom after the plane of polarization thereof has been rotated by an angle of +45° while the light component entering into the left side portion of this halving optical element 38 for optical rotation is emitted therefrom after the plane of polarization thereof has been rotated by an angle of −45°. The light component to be derived from the S-polarized light component whose polarization plane has been rotated by an angle of +450 (or the light component to be derived from the P-polarized light component whose polarization plane has been rotated by an angle of −45°) will be hereinafter referred to as an A-polarized light component, while the light component to be derived from the S-polarized light component whose polarization plane has been rotated by an angle of −45° (or the light component to be derived from the P-polarized light component whose polarization plane has been rotated by an angle of +45°) will be hereinafter referred to as a B-polarized light component. Incidentally, each of the right and left portions of the halving optical element 38 for optical rotation may be constructed by a half-wavelength plate.

The A-polarized light component and the B-polarized light component that have been emitted from the halving optical element 38 for optical rotation are converged on the reflection layer 22 of holographic recording medium 21 by an objective lens 34. Incidentally, the holographic recording medium 21 is arranged such that the transparent substrate 25 faces the objective lens 34.

On the other hand, part of the P-polarized light component (reference light) that has passed through the polarized beam splitter 29 is reflected by the beam splitter 39 and then passed through the polarized beam splitter 37. This reference light that has passed through the polarized beam splitter 37 is then transmitted into the halving optical element 38 for optical rotation. The light component entering into the right side portion of this halving optical element 38 for optical rotation is emitted therefrom as a B-polarized light component after the plane of polarization thereof has been rotated by an angle of +45°, while the light component entering into the left side portion of this halving optical element 38 for optical rotation is emitted therefrom as an A-polarized light component after the plane of polarization thereof has been rotated by an angle of −45°. Subsequently, the A-polarized light component and B-polarized light component are converged on the reflection layer 22 of holographic recording medium 21 by an objective lens 34.

As described above, the information light constituted by the A-polarized light component and the reference light constituted by the B-polarized light component are emitted from the right side portion of the halving optical element 38 for optical rotation. On the other hand, the information light constituted by the B-polarized light component and the reference light constituted by the A-polarized light component are emitted from the left side portion of the halving optical element 38 for optical rotation. Furthermore, the information light and reference light are enabled to converge on the reflection layer 22 of holographic recording medium 21.

Because of this, interference between the information light and the reference light take place only between the information light formed of the direct light that has been directly transmitted into the recording layer 26 through the transparent substrate 25 and the reference light formed of the reflection light that has been reflected by the reflection layer 22, and between the reference light formed of a direct light and the information light formed of a reflection light. Furthermore, neither the interference between the information light formed from a direct light and the information light formed from a reflection light, nor the interference between the reference light formed from a direct light and the reference light formed from a reflection light can be prevented from generating. Therefore, according to the recording/regenerating apparatus shown in FIG. 4, it is possible to generate a distribution of optical properties in the recording layer 26 in conformity with the information light.

For the case of the reflection type holographic recording/regenerating apparatus shown in FIG. 4, it is also possible to install the ultraviolet source device and the ultraviolet irradiating optical system, as already explained above, in order to enhance the stability of the recorded hologram.

The information recorded according to the aforementioned method can be read out as explained below. Namely, the electromagnetic shutter 33 is closed to enable only the reference light to emit, thus irradiating the recording layer 26 having information recorded therein in advance. As a result, only the reference light formed of the P-polarized light component reaches the halving optical element 38 for optical rotation.

Due to the effects of the halving optical element 38 for optical rotation, this reference light is processed such that the light component entering into the right side portion of this halving optical element 38 for optical rotation is emitted therefrom as a B-polarized light component after the plane of polarization thereof has been rotated by an angle of +45°, while the light component entering into the left side portion of this halving optical element 38 for optical rotation is emitted therefrom as an A-polarized light component after the plane of polarization thereof has been rotated by an angle of −45°. Subsequently, the A-polarized light component and B-polarized light component are converged on the reflection layer 22 of holographic recording medium 21 by the objective lens 34.

In the recording layer 26 of the holographic recording medium 21, there is formed, according to the aforementioned method, a distribution of optical properties created in conformity with the information to be recorded. Accordingly, part of the A-polarized light component and B-polarized light component that have been emitted to the holographic recording medium 21 is diffracted by the distribution of optical properties created in the recording layer 26 and is then emitted as a regenerating light from the holographic recording medium 21.

In the regenerating light emitted from the holographic recording medium 21, the information light is reproduced therein, so that the regenerating light is formed into a parallel light by the objective lens 34 which then reaches the halving optical element 38 for optical rotation. The B-polarized light component transmitted into the right side portion of the halving optical element 38 for optical rotation is emitted therefrom as the P-polarized light component. Further, the A-polarized light component transmitted into the left side portion of the halving optical element 38 for optical rotation is emitted therefrom also as the P-polarized light component. In this manner, it is possible to obtain a regenerating light as the P-polarized light component.

Thereafter, the regenerated light passes through the polarized beam splitter 37. Part of the regenerating light that has passed through the polarized beam splitter 37 then passes through the beam splitter 39 and is transmitted through an image-forming lens 35 to the two-dimensional beam detector 36, thereby reproducing an image of the transmission type special beam modulator 31 on the two-dimensional beam detector 36. In this manner, it is possible to read out the information recorded in the holographic recording medium 21.

On the other hand, the remainder of the A-polarized light component and of the B-polarized light component that have been transmitted through the halving optical element 38 for optical rotation into the holographic recording medium 21 are reflected by the reflection layer 22 and emitted from the holographic recording medium 21. The A-polarized light component and B-polarized light component that have been reflected as a reflection light are then turned into a parallel light by the objective lens 34. Subsequently, the A-polarized light component of this parallel light is transmitted into the right side portion of the halving optical element 38 and then emitted therefrom as the S-polarized light component, while the B-polarized light component of this parallel light is transmitted into the left side portion of the halving optical element 38 for optical rotation and then emitted therefrom as the S-polarized light component. Since the S-polarized light component thus emitted from the halving optical element 38 for optical rotation is reflected by the polarized beam splitter 37, it is impossible for the S-polarized light component to reach the two-dimensional beam detector 36. Therefore, according to this recording/regenerating apparatus, it is now possible to realize an excellent regenerating signal-to-noise ratio.

The holographic recording medium according to one embodiment can be suitably employed for the multi-layer optical recording and regeneration of information. This multi-layer recording and regeneration of information may be of any type, i.e., either the transmission type or the reflection type.

Next, the present invention will be further explained with reference to specific examples.

### Example 1

4.54 g of 1,6-hexanediol diglycidyl ether (epoxy equivalent: 151; Nagase Chemtex Corporation) as an epoxy monomer and 0.364 g of aluminum tris(ethylacetyl acetate) as a metal complex were mixed with each other in a dark room to obtain a mixture. This mixture was then dissolved under stirring at a temperature of 60° C. to prepare a metal complex solution.

Separately, 4.55 g of 1,6-hexanediol diglycidyl ether (epoxy equivalent: 151; Nagase Chemtex Corporation) as an epoxy monomer and 0.545 g of triphenyl silanol as an alkyl silanol were mixed with each other to obtain a mixture. This mixture was then dissolved under stirring at a temperature of 60° C. to prepare a silanol solution.

The metal complex solution and the silanol solution were mixed with each other under stirring. 0.38 g of a ring-opening polymerizable compound and 0.025 g of a photo-radical generating agent were added to the resulting solution. 1-cyclopropyl-1-phenyl ethene, represented by the chemical formula (PM-1) below, was used as the ring-opening polymerizable compound, and Irgacure 784 (Chiba Speciality Chemicals Co., Ltd.) was used as the photo-radical generating agent. Finally, the resultant mixture was defoamed to obtain a raw material solution for a recording layer.

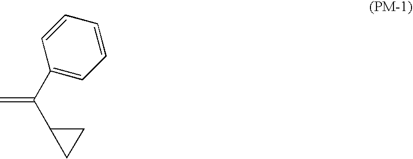

A pair of glass plates were superimposed with a spacer formed of a Teflon (registered trademark) sheet interposed therebetween to form a space. Then, the aforementioned raw material solution for a recording layer was poured into this space. The resultant structure was heated in an oven at 55° C. for 6 hours under a light-shielded condition, thereby manufacturing a test piece of the holographic recording medium bearing a recording layer having a thickness of 200 μm.

The characteristics of the holographic recording medium are evaluated by using a generally used plane-wave measuring device. As the light source device, a semiconductor laser (405 nm) was used. The light spot size on the test piece was 5 mmφ in diameter in each of the information light and the reference light. The intensity of the recording light was adjusted such that the total of the information light and the reference light became 7 mW/cm².

After finishing hologram recording, the information light was shut off, and only the reference light only was applied onto the test piece, and as a result, diffracted light from the test piece was recognized. Based on this fact, the existence of a transmission type hologram recorded therein was confirmed.

The hologram recording performance was assessed by M/# (M number), representing a dynamic range of recording. M/# can be defined by the following formula using ηᵢ. ηᵢ represents a diffraction efficiency derived from i-th hologram when holograms of n pages are subjected to angular multiple recording/regeneration until the recording at the same region in the recording layer of the holographic recording medium becomes no longer possible. This angular multiple recording/regeneration can be performed by applying a predetermined light to the holographic recording medium while rotating the medium.

$$M / \# = {\sum }_{i = 1}^{n} \sqrt{η i}$$

Incidentally, the diffraction efficiency η was defined by the light intensity Iₜ detected at the light detector and the light intensity I_{d} detected at the light detector, upon irradiation of the holographic recording medium with only the reference light. Namely, the diffraction efficiency was defined by an inner diffraction efficiency which can be represented by η=I_{d}/(Iₜ+I_{d}).

As the value of M/# of the holographic recording medium becomes larger, the dynamic range of recording is further enlarged, thus indicating a higher multiple recording performance.

The M/# of the recording medium was 5.3, and the volumetric shrinkage ratio due to the recording was almost 0%. The volumetric shrinkage ratio was determined by a measurement method described by Lisa Dahl et al. in Applied Physics Letters Vol. 73, No. 10, p. 1337 (1998). A shrinkage ratio of less than 0.3% can be regarded as not substantially generating volumetric shrinkage and is in the allowable range.

### Example 2

A medium in Example 2 was manufactured in the same manner as in Example 1 except that the ring-opening polymerizable compound was changed to 1-cyclopropyl-1-tribromophenyl ethene represented by the chemical formula (PM-2) below. The M/# of the recording medium was 9.0, and the volumetric shrinkage ratio due to the recording was almost 0%.

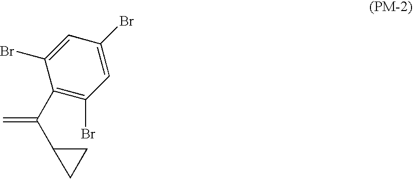

### Example 3

A medium in Example 3 was manufactured in the same manner as in Example 1 except that a 1-cyclopropyl-1-phenyl ethene radical polymerizable compound (Compound 1) was used in an amount of 0.19 g as the ring-opening polymerizable compound and vinyl naphthalene was used in an amount of 0.19 g as a usual radical polymerizable compound. The M/# of the recording medium was 8.0, and the volumetric shrinkage ratio due to the recording was 0.02%.

### Example 4

A medium in Example 4 was manufactured in the same manner as in Example 1 except that the ring-opening polymerizable compound was changed to the compound represented by the chemical formula (PM-3) below. The M/# of the recording medium was 6.5, and the volumetric shrinkage ratio due to the recording was almost 0%.

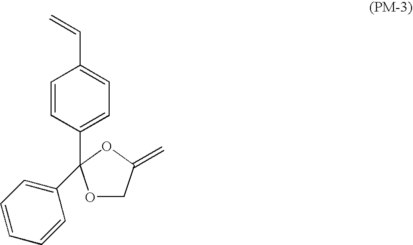

### Example 5

A medium in Example 5 was manufactured in the same manner as in Example 1 except that the ring-opening polymerizable compound was used in an amount of 0.19 g as the ring-opening polymerizable compound and vinyl naphthalene was used in an amount of 0.19 g as a usual radical polymerizable compound. The M/# of the recording medium was 9.0, and the volumetric shrinkage ratio due to the recording was 0.02%.

### Example 6

A medium in Example 6 was manufactured in the same manner as in Example 1 except that the ring-opening polymerizable compound was changed to the compound represented by the chemical formula (PM-4) below. The M/# of the recording medium was 5.5, and the volumetric shrinkage ratio due to the recording was almost 0%.

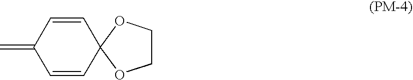

### Example 7

A medium in Example 7 was manufactured in the same manner as in Example 1 except that the ring-opening polymerizable compound was changed to the compound represented by the chemical formula (PM-5) below. The M/# of the recording medium was 6.0, and the volumetric shrinkage ratio due to the recording was almost 0%.

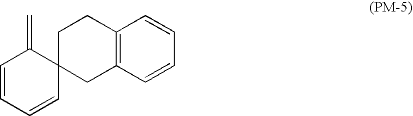

### Comparative Example 1

A medium in Comparative Example 1 was manufactured in the same manner as in Example 1 except that the ring-opening polymerizable compound (PM-1) was changed to 1-propyl-4-vinylbenzene. The M/# of the recording medium was 4.0, and the volumetric shrinkage ratio due to the recording was 0.4%.

### Comparative Example 2

A medium in Comparative Example 2 was manufactured in the same manner as in Example 1 except that the ring-opening polymerizable compound (PM-1) was changed to 2-vinylnaphthalene. The M/# of the recording medium was 9.8, and the volumetric shrinkage ratio due to the recording was 0.7%.

### Comparative Example 3

A medium in Comparative Example 3 was manufactured in the same manner as in Example 1 except that a 1-cyclopropyl-1-phenyl ethene radical polymerizable compound was used in an amount of 0.038 g as the ring-opening polymerizable compound and vinyl naphthalene was used in an amount of 0.342 g as a usual radical polymerizable compound. The M/# of the recording medium was 9.0, and the volumetric shrinkage ratio due to the recording was 0.65%.

In the holographic recording mediums in the embodiments, the ring-opening polymerizable compound spreads easily, thus attaining a high recording capacity and high refractive-index modulation. In addition, the radically ring-opening polymerizable compound is contained in the recording layer, so volumetric shrinkage can be suppressed.

On the other hand, it is shown in Comparative Examples 1 and 2 that when the radically ring-opening polymerizable compound is not contained, volumetric shrinkage higher than the allowable range is generated regardless of the type of the radical polymerizable compound. From the result in Comparative Example 3, it can be seen that even if the radically ring-opening polymerizable compound is contained, the volumetric shrinkage cannot be suppressed where the vinyl compound is contained in excess.

According to the embodiment of the present invention, there is provided a holographic recording medium with high recording capacity and high refractive-index modulation with less change in volumetric shrinkage upon light irradiation.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A holographic recording medium, comprising a recording layer containing a three-dimensional crosslinked polymer matrix; a photo-radical generating agent; and a ring-opening polymerizable compound having a radically ring-opening polymerizable alicyclic structure.

2. The holographic recording medium according to claim 1, wherein the alicyclic structure contained in the ring-opening polymerizable compound is selected from the group consisting of a cyclic sulfide structure, a bicyclobutane structure, a vinylcyclopropane structure, a vinyl cyclic sulfone structure, a 4-methylene-1,3-dioxolane structure, a cyclic ketene acetal structure, an 8-methylene-1,4-dioxaspiro-[4,5]-deca-6,9-diene structure, a cyclic allylsulfide structure, a cyclic α-oxyacrylate structure, a benzocyclobutene structure, an o-xylylene dimer structure, a structure having in its molecule an exomethylene structure and a spiro-orthocarbonate structure, and a structure having in its molecule an exomethylene structure and a spiro-orthoester structure.

3. The holographic recording medium according to claim 1, wherein the alicyclic structure contained in the ring-opening polymerizable compound is selected from the group consisting of 1-cyclopropyl-1-phenyl ethene, 1-cyclopropyl-1-tribromophenyl ethene, and 1-cyclopropyl-1-naphthyl ethene.

4. The holographic recording medium according to claim 1, wherein the ring-opening polymerizable compound is contained in an amount of 1 to 40% by weight based on a whole of the recording layer.

5. The holographic recording medium according to claim 1, wherein the ring-opening polymerizable compound is contained in an amount of 5 to 15% by weight based on a whole of the recording layer.

6. The holographic recording medium according to claim 1, wherein the three-dimensional crosslinked polymer matrix contains a structure represented by following formula 7: 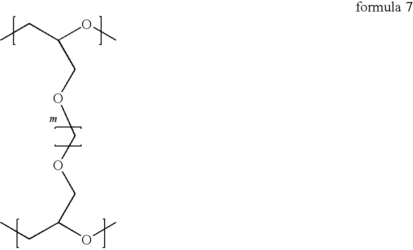
wherein m is an integer of 3 to 16.

7. The holographic recording medium according to claim 1, wherein the three-dimensional crosslinked polymer matrix is obtained by polymerizing an epoxy monomer through epoxy-amine polymerization, epoxy-acid anhydride polymerization, or epoxy homopolymerization.

8. The holographic recording medium according to claim 1, wherein the photo-radical generating agent is selected from the group consisting of imidazole derivatives, organic azide compounds, titanocenes, organic peroxides, and thioxanthone derivatives.

9. The holographic recording medium according to claim 1, wherein the photo-radical generating agent is contained in an amount of 0.1 to 10% by weight based on the ring-opening polymerizable compound.

10. The holographic recording medium according to claim 1, wherein the photo-radical generating agent is contained in an amount of 0.5 to 6% by weight based on the ring-opening polymerizable compound.

11. The holographic recording medium according to claim 1, wherein the recording layer further contains a vinyl compound in an amount of less than 3/2 relative to the weight of the ring-opening polymerizable compound.

12. The holographic recording medium according to claim 11, wherein the vinyl compound is selected from the group consisting of vinyl naphthalene, halogenated phenyl acrylate, halogenated phenyl methacrylate, and vinyl carbazole.

13. The holographic recording medium according to claim 1, wherein the recording layer further contains at least one selected from the group consisting of a sensitizer, a silane coupling agent, and a plasticizer.

14. The holographic recording medium according to claim 1, wherein the recording layer has a thickness of 0.1 to 5 mm.

15. The holographic recording medium according to claim 1, wherein the recording layer has a thickness of 0.2 to 2 mm.

16. A method for manufacturing a holographic recording medium, comprising:
mixing an epoxy monomer, an alkyl silanol, a metal complex, a photo-radical generating agent, and a ring-opening polymerizable compound to obtain a raw material solution for a recording layer;
applying the raw material solution for a recording layer onto a light-transmitting substrate or interposing the raw material solution between a pair of facing light-transmitting substrates, to form a resin layer; and
heating the resin layer at a temperature in the range of from 10° C. to less than 80° C. to polymerize the epoxy monomer, thereby forming a recording layer having a three-dimensional crosslinked polymer matrix including a structure represented by following formula 7: 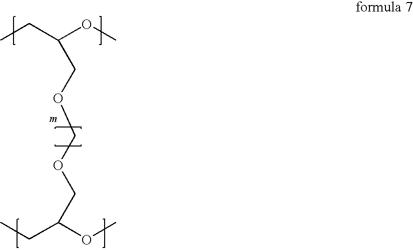
wherein m is an integer of 3 to 16.

17. The method according to claim 16, wherein the epoxy monomer is a compound represented by following formula 1: 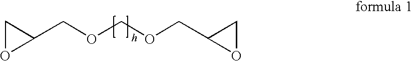
wherein h is an integer of 8 to 12.

18. The method according to claim 16, wherein the alkyl silanol is a compound represented by following formula 5: 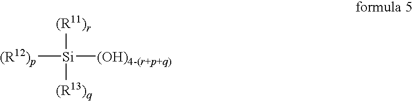
wherein R¹¹, R¹² and R¹³ may be the same or different and are selected from the group consisting of a substituted or unsubstituted alkyl group having 1 to 30 carbon atoms, a substituted or unsubstituted aromatic group having 6 to 30 carbon atoms, and a substituted or unsubstituted aromatic heterocyclic group having 3 to 30 carbon atoms; and p, q and r each represent an integer of 0 to 3 with a proviso that p+q+r is 3 or less.

19. The method according to claim 16, wherein the metal complex is a compound represented by following formula 2, 3, or 4: 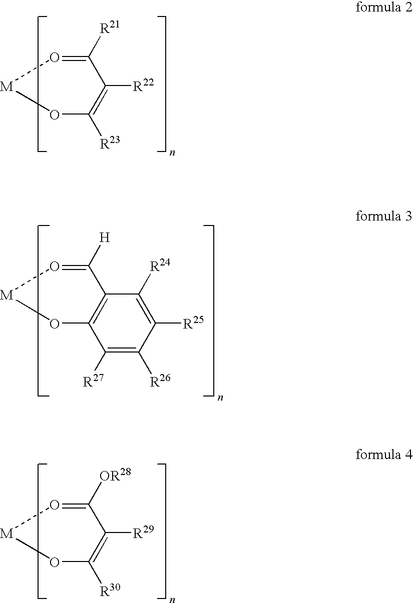
wherein M is selected from the group consisting of Al, Ti, Cr, Mn, Fe, Co, Ni, Cu, Zr, Zn, Ba, Ca, Ce, Pb, Mg, Sn and V; R²¹, R²² and R²³ may be the same or different and are selected from the group consisting of a hydrogen atom and a substituted or unsubstituted alkyl group having 1 to 10 carbon atoms; R²⁴, R²⁵, R²⁶ and R²⁷ may be the same or different and are selected from the group consisting of a hydrogen atom and a substituted or unsubstituted alkyl group having 1 to 10 carbon atoms; R²⁸, R²⁹ and R³⁰ may be the same or different and are selected from the group consisting of a hydrogen atom and a substituted or unsubstituted alkyl group having 1 to 10 carbon atoms; and n is an integer of 2 to 4.

20. An optical information recording/regenerating apparatus comprising:
the aforementioned holographic recording medium according to claim 1;
a recording portion for recording information in the medium; and
a regenerating portion for regenerating the information recorded in the medium.
